(19) United States
(12) Patent Application Publication
(10) Pub. No.: US 2026/0367008 A1
(43) Pub. Date: Nov. 19, 2026

(54) SYSTEM AND METHOD FOR SPECTROMETER CROSSTALK REDUCTION

(71) Applicant: Verity Instruments, Inc., Carrollton, TX (US)

(72) Inventors: John Corless, Carrollton, TX (US); Andrew Kueny, Carrollton, TX (US); Patrick Abbott, Carrollton, TX (US)

(21) Appl. No.: 19/662,512

(22) Filed: Apr. 29, 2026

Related U.S. Application Data
(60) Provisional application No. 63/806,267, filed on May 15, 2025.

(51) Int. Cl. G01N 21/71; G01B 11/06; H10P 72/00

(52) U.S. Cl. CPC G01N 21/718; G01B 11/0675; H10P 72/0604; G01N 2201/08

(57) ABSTRACT

The disclosure provides features for reducing crosstalk between channels in a multichannel optical spectrometer. In one example, the disclosure provides a method for reducing the crosstalk that includes: (1) collecting a plurality of optical signals from a plurality of channels defined upon an optical sensor of the multichannel optical spectrometer, (2) digitizing and storing the plurality of signals, and (3) modifying one or more of the plurality of digitized and stored signals to reduce signal crosstalk, wherein the modifying is based at least on a number of the channels, a clock speed of the optical sensor, and an integration time of the collecting of the plurality of optical signals.

### CROSS-REFERENCE TO RELATED APPLICATION

This application claims the benefit of U.S. Provisional Application Ser. No. 63/806,267, filed by John Corless, et al., on May 15, 2025, entitled “SYSTEM AND METHOD FOR SPECTROMETER CROSSTALK REDUCTION”, which is commonly assigned with this application and incorporated herein by reference in its entirety.

### TECHNICAL FIELD

This disclosure relates, generally, to optical spectroscopy systems and methods of use, and more specifically, to improvements to systems and methods for the reduction of the effects of crosstalk (or simply referred to as the reduction of crosstalk) between optical signals collected by CCD-based spectrometers during monitoring of semiconductor processes from semiconductor processing equipment.

### BACKGROUND

Optical monitoring of semiconductor processes is a well-established method for controlling processes such as etch, deposition, chemical mechanical polishing and implantation. Optical emission spectroscopy (OES) and interferometric endpoint (IEP) are two basic types of modes of operation for data collection. In OES applications light emitted from the process, typically from plasmas, is collected and analyzed to identify and track changes in atomic and molecular species which are indicative of the state or progression of the process being monitored. In IEP applications, light is typically supplied from an external source, such as a flashlamp, and directed onto a workpiece. Upon reflection from the workpiece, the sourced light carries information, in the form of the reflectance of the workpiece, which is indicative of the state of the workpiece. Extraction and modeling of the reflectance of the workpiece permits understanding of film thickness and feature sizes/depth/widths among other properties.

### SUMMARY

In one aspect, the disclosure provides a method for reducing crosstalk between channels in a multichannel optical spectrometer. In one example, the method includes: (1) collecting a plurality of optical signals from a plurality of channels defined upon an optical sensor of the multichannel optical spectrometer, (2) digitizing and storing the plurality of signals, and (3) modifying one or more of the plurality of digitized and stored signals to reduce signal crosstalk, wherein the modifying is based at least on a number of the channels, a clock speed of the optical sensor, and an integration time of the collecting of the plurality of optical signals.

In another aspect, a multichannel optical spectrometer with crosstalk reducing functionality is disclosed. In one example, the multichannel optical spectrometer includes: (1) a two-dimensional optical sensor for collecting a plurality of optical signals, the two-dimensional optical sensor configured into a plurality of channels, (2) circuitry for digitizing and storing the plurality of signals each from one of the plurality of channels, and (3) a processor for modifying one or more of the plurality of digitized and stored signals to reduce signal crosstalk, wherein the modifying is based at least on a number of the channels, a clock speed of the optical sensor, and an integration time of the collecting of the plurality of optical signals.

In yet another aspect, the disclosure provides an optical processing system with crosstalk reducing functionality. In one example, the optical processing system includes: (1) a multichannel optical spectrometer having: (1A) a two-dimensional optical sensor for collecting a plurality of optical signals, the two-dimensional optical sensor configured into a plurality of channels, (1B) circuitry for digitizing and storing the plurality of signals each from one of the plurality of channels, and (1C) a first processor for at least partially modifying one or more of the plurality of digitized and stored signals to reduce signal crosstalk based at least on a number of the channels, a clock speed of the optical sensor, or an integration time of the collecting of the plurality of optical signals. The example optical processing system also includes: (2) a second processor, external to the multichannel optical spectrometer, for at least partially modifying one or more of the plurality of digitized and stored signals to reduce signal crosstalk based at least on a number of the channels, a clock speed of the optical sensor, and an integration time of the collecting of the plurality of optical signals.

In still another aspect, the disclosure provides a non-transitory computer-readable medium having a series of operating instructions stored thereon that direct operations of a processor when initiated to perform operations comprising: (1) collecting a plurality of optical signals from a plurality of channels defined upon an optical sensor of a multichannel optical spectrometer, (2) digitizing and storing the plurality of signals, and (3) modifying one or more of the plurality of digitized and stored signals to reduce signal crosstalk based at least on a number of the channels, a clock speed of the optical sensor, and an integration time of the collecting of the plurality of optical signals.

### BRIEF DESCRIPTION OF THE DRAWINGS

Reference is now made to the following descriptions taken in conjunction with the accompanying drawings, in which:

FIG. 1 is a block diagram of a system for employing OES and/or IEP to monitor and/or control the state of a plasma or non-plasma process within a semiconductor process tool;

FIG. 2 is a diagram representing the simplified functional elements of a two-dimensional optical CCD (“charge couple device”) sensor;

FIGS. 3A-3I are a set of block diagrams and mathematical descriptions indicating sequencing and collection of certain signals and their associated regions of a CCD sensor;

FIG. 4 is a plot of an example of data collected in accordance with the block diagrams and sequencing of FIGS. 3A-3I;

FIG. 5 is flow chart detailing the steps for reducing electrical crosstalk from data such as shown in FIG. 4 and collected in accordance with the block diagrams and sequencing of FIGS. 3A-3I;

FIGS. 6A-6C are a set of mathematical descriptions for the collected signals and models used for the modification of the signals according to this disclosure;

FIGS. 7-10 are a set of plots showing resultant signals following the application of the crosstalk reduction techniques and other processing as disclosed herein;

FIG. 11 illustrates a block diagram of multiple optical, electrical, and computational components of a spectrometer and specific related systems in accordance with the principles of the disclosure; and

FIG. 12 illustrates a computing device that can be used for processes disclosed herein, such as identifying signals in spectral data and processing the signals.

### DETAILED DESCRIPTION

In the following description, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized. It is also to be understood that structural, procedural and system changes may be made without departing from the spirit and scope of the present invention. The following description is, therefore, not to be taken in a limiting sense. For clarity of exposition, like features shown in the accompanying drawings are indicated with like reference numerals and similar features as shown in alternate embodiments in the drawings are indicated with similar reference numerals. Other features of the present invention will be apparent from the accompanying drawings and from the following detailed description. It is noted that, for purposes of illustrative clarity, certain elements in the drawings may not be drawn to scale.

Continued advancement of semiconductor device technology and the decrease in feature sizes of such technology lead to more complex and difficult to measure, characterize, and analyze data streams, which must be monitored and processed to provide control of semiconductor processes. Herein various continuous and discontinuous optical signals are discussed. Any of these optical signals may result from one or more sources such as lamps, plasma emissions, ambient lighting, etc. The mixing of these optical signals and the resulting confusion of interpretation of such mixed signals poses challenges for use that the details of this disclosure seek to remedy. Although previous techniques such as described in US Patent Application Publication US2006/0012796 entitled “Plasma Treatment Apparatus and Light Detection Method of a Plasma Treatment” and U.S. Pat. No. 9,386,241 entitled “Apparatus and Method for Enhancing Dynamic Range of Charge Coupled Device-based Spectrograph,” both included by reference herein, seek to reduce signal mixing and enhance signal dynamic range, these techniques fail to extensively remedy these issues or provide significant limitations. Specifically, the techniques of US Patent Application Publication US2006/0012796 require the shielding and loss of function of a large portion, typically 50%, of the active sensor pixel region, which results in the loss of ability to collect signals and/or added cost and complexity for larger sensors. Furthermore, the techniques of U.S. Pat. No. 9,386,241 are generally applicable to single signals and the adaptation to include multiple signals may result in a worsening of the contributions to signal crosstalk. Accordingly, further improvements to, for example, reduce mixing signals associated with the optical signals or enhance signal dynamic range would be beneficial.

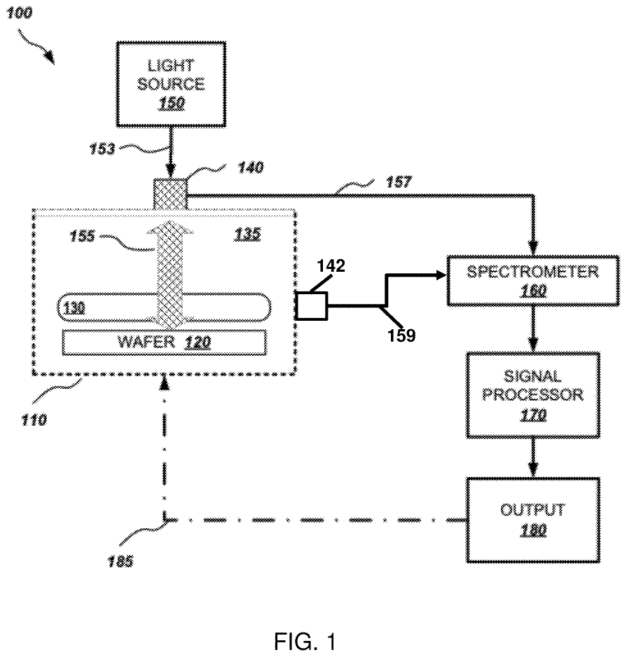

With specific regard to monitoring and evaluating the state of a semiconductor process within a process tool, FIG. 1 illustrates a block diagram of process system 100 utilizing OES and/or IEP to monitor and/or control the state of a plasma or non-plasma process within a semiconductor process tool 110. Semiconductor process tool 110, or simply process tool 110, generally encloses a workpiece, which is represented by wafer 120 in FIG. 1, and possibly process plasma 130 in a typically, partially evacuated volume of a processing chamber 135 that may include various process gases. Process tool 110 may include one or multiple optical interfaces 140 and 142 to permit observation into the processing chamber 135 at various locations and orientations. Interfaces 140 and 142 may include multiple types of optical elements such as, but not limited to, optical filters, lenses, windows, apertures, mirrors, beamsplitters, fiber optics, etc.

For IEP applications, light source 150 may be connected with interface 140 directly or via fiber optical cable assembly 153. Light source 150 may, for example, be a discontinuous pulsed Xenon source such as the FL2100 series flashlamps from Verity Instruments of Carrollton Texas. As shown in this configuration, interface 140 is oriented normal to the surface of wafer 120 and often centered with respect to the same. Light from light source 150 may enter the internal volume of processing chamber 135 in the form of collimated beam 155. Beam 155 upon reflection from the wafer 120 may again be received by interface 140. In common applications, interface 140 may be an optical collimator. Following receipt by interface 140, the light may be transferred via fiber optic cable assembly 157 to spectrometer 160 for detection and conversion to digital signals. The light received at spectrometer 160 can include sourced (e.g., from light source 150) and detected (e.g., from plasma 130) light and may include, for example, the wavelength range from deep ultraviolet (DUV) to near-infrared (NIR). Wavelengths of interest may be selected from any subrange of the wavelength range.

For OES applications, interfaces such as interfaces 140 and 142 may be used to collect light emitted from plasma 130. As shown, interface 140 is oriented normal to the surface of wafer 120 and interface 142 is non-normal, such as parallel to the surface of wafer 120. These differences in orientation may permit collection of different optical signals proving varied information regarding the state of the processing of wafer 120. Whereas interface 140 may be an optical collimator, interface 142 may be a collimator or simply a lens or window providing optical access to the light emitted from the plasma. Following receipt by interfaces 140 and 142, the OES plasma light signals may be transferred via fiber optic cable assemblies 157 and 159 respectively to spectrometer 160 for detection and conversion to digital signals. The OES plasma light signals may include, for example, the wavelength range from deep ultraviolet (DUV) to near-infrared (NIR). Wavelengths of interest may be selected from any subrange of the wavelength range. The OES plasma light signals may be continuous from a continuously excited plasma or may be discontinuous from a pulsed plasma.

As shown in FIG. 1., fiber optic cable assemblies 157 and 159 each provide optical signals to spectrometer 160 which may be configured to accept assemblies 157 and 159 as a single physical two-channel fiber optic interface. After detection and conversion of the received optical signals to analog electrical signals by the spectrometer 160, the analog electrical signals are typically amplified and digitized within a subsystem of spectrometer 160 and passed to signal processor 170. Signal processor 170 may be, for example, an industrial PC, PLC or other system, which employs one or more algorithms to produce output 180 such as, for example, an analog or digital control value representing the intensity of a specific wavelength or the ratio of two wavelength bands or modified signals as disclosed herein. Instead of a separate device, signal processor 170 may alternatively be integrated with spectrometer 160. The signal processor 170 may employ an OES algorithm that analyzes emission intensity signals at predetermined wavelength(s) and determines trend parameters that relate to the state of the process and can be used to access that state, for instance end point detection, etch depth, etc. For IEP applications, the signal processor 170 may employ an algorithm that analyzes wide-bandwidth portions of spectra to determine a film thickness. For example, see System and Method for In-situ Monitor and Control of Film Thickness and Trench Depth, U.S. Pat. No. 7,049,156, incorporated herein by reference. Output 180 may be transferred to process tool 110 via communication link 185 for monitoring and/or modifying the production process occurring within chamber 135 of the process tool 110. The output 180 can be an analog or digital control signal that directs operation of the process tool 110 or processing chamber 135 to control processing in the processing chamber 135, such as the processing of the wafer 120. A control signal may be, for example, a single digital binary value (e.g., 0 or 1) indicating that the process tool should continue or halt an ongoing process by, for example, terminating power to a process plasma source. Other control signals may include, for example, scalar or vector values directing one or more subsystems of a processing tool to alter an operating parameter such as to increase or decrease the power level supplied to a process plasma source or to increase or decrease a process pressure within a process chamber. In general, control signals may be used for modification of any adjustable or configurable operating parameter (e.g., pressures, power level, gas flow) or physical state (e.g., instruct a valve to move) of a processing tool.

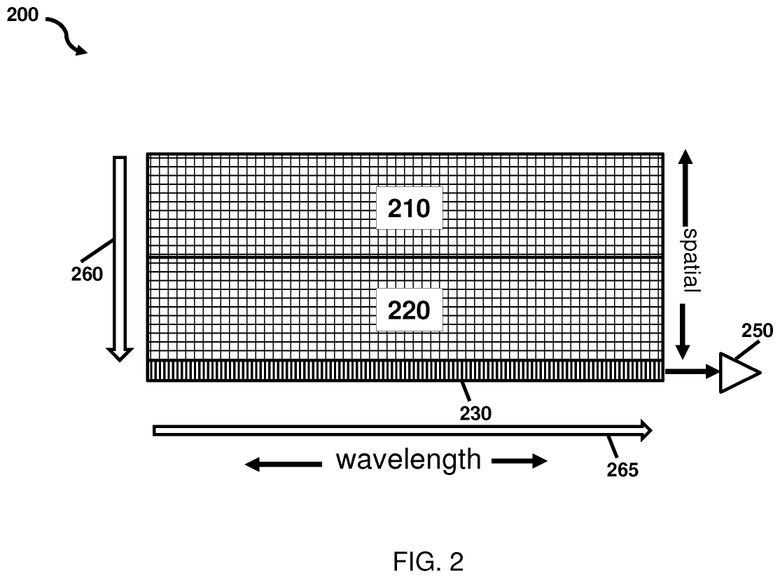

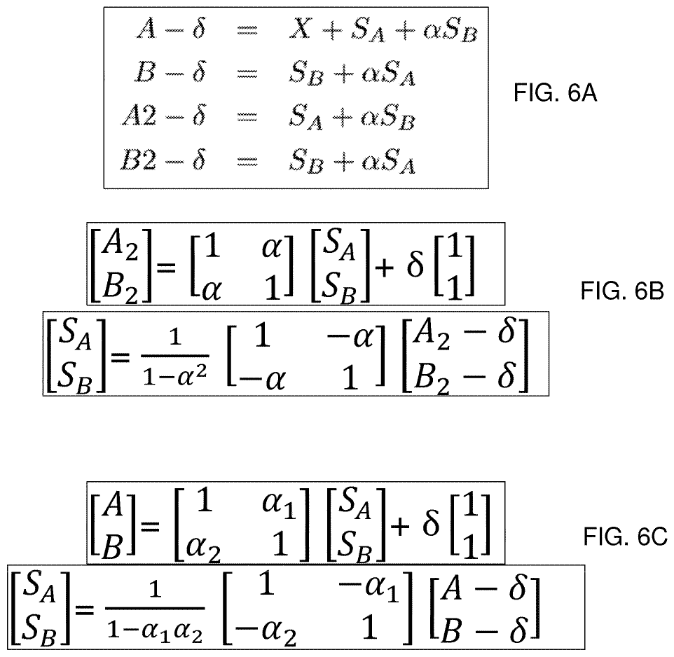

The shown and described components of FIG. 1 are simplified for expedience and are commonly known. In addition to common functions, the spectrometer 160 or the signal processor 170 can also be configured to identify stationary and transient optical and non-optical signals and process these signals according to the methods and/or features disclosed herein. As such, the spectrometer 160 or the signal processor 170 can include algorithms, processing capability, and/or logic corresponding to the collection, analysis, and crosstalk reduction between channels in a multichannel optical spectrometer, such as represented in FIGS. 6A to 6B. The crosstalk reduction can improve the output 180 to improve control signals for controlling processing in the processing chamber 135. The algorithms, processing capability, and/or logic can be in the form of hardware, software, firmware, or any combination thereof. The algorithms, processing capability, and/or logic can be within one computing device or can also be distributed over multiple devices, such as the spectrometer 160 and the signal processor 170. Spectrometer 160 can be a CCD-based spectrometer having a CCD sensor, such as CCD sensor 200 of FIG. 2.

FIG. 2 shows a diagram representing the simplified functional elements of a two-dimensional optical CCD sensor 200. Sensor 200 may be for example a S7031 series 1024×128 horizontal-by-vertical pixel CCD sensor from Hamamatsu of Japan. In association with the description of FIG. 1 and the discussion following, this disclosure will relate the optical signal collection, analysis and crosstalk reduction of the improvements discussed herein using a two-channel configuration of a spectrometer, such as spectrometer 160, as an example. It should be generally recognized that the following discussion may be applied to other CCD-based spectrometers including two or more channels. Furthermore, channels defined for the spectrometer may include a various number of horizontal and vertical rows of pixels and each channel may differ in pixel extent from any of the other channels.

Optical CCD sensor 200, or simply sensor 200, includes an active pixel region and a shift register 230. The active pixel region may be divided into, for example, two equal regions 210 and 220. Herein regions 210 and 220 may also be referred to as Channel A (Ch A) and Channel B (Ch B) respectively. In this example each region 210 and 220 may include an areal 2D array of 1024×64 active pixels. As indicated by arrow 265 the long axis of sensor 200 is oriented with the wavelength dispersion direction. The orientation of arrow 265 is generally denominated as the “horizontal” direction and the direction of arrow 265 indicates the charge shifting direction through and out of shift register 230. Short axis of sensor 200 as indicated by arrow 260 is associated with a spatial dimension of the channel. The orientation of arrow 260 is generally denominated as the “vertical” direction and the direction of arrow 260 indicates the charge shifting direction towards shift register 230.

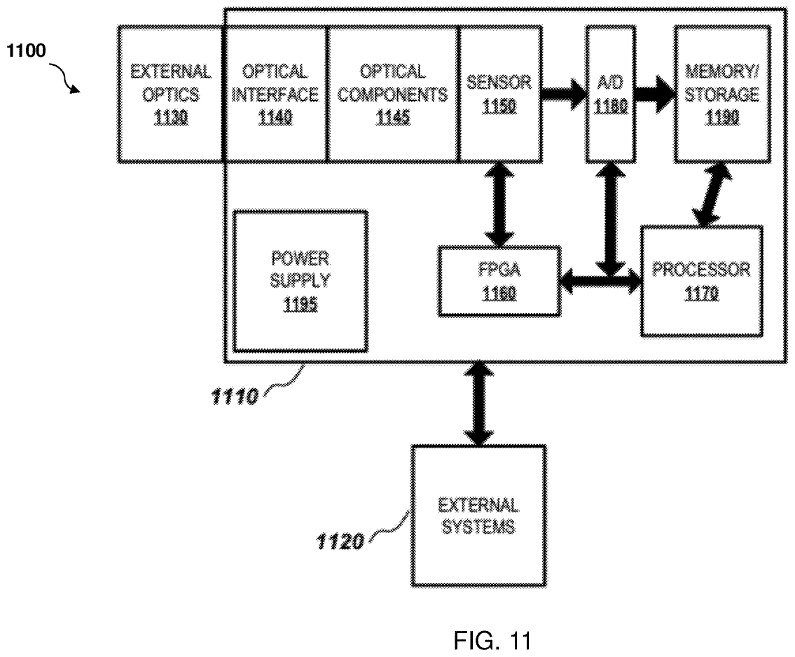

The shift register 230 is connected with circuitry 250. Active pixels of sensor 200 within regions 210 and 220 accumulate charge derived from the incident light for a predetermined integration time and when commanded by a processor shifts the accumulated charge according to the directions indicated by arrows 260 and 265. General operation of sensor 200 includes vertically shifting one or more rows of accumulated charge simultaneously across all columns of the areal array of active pixels into shift register 230 and then horizontally shifting the charge collected in the shift register 230 into the circuitry for digitization and storage. The vertical and horizontal shifting is controlled by a processor and other subsystem components, detailed herein in association with FIG. 11, and is performed at a predetermined clock rate e.g., 100 KHz.

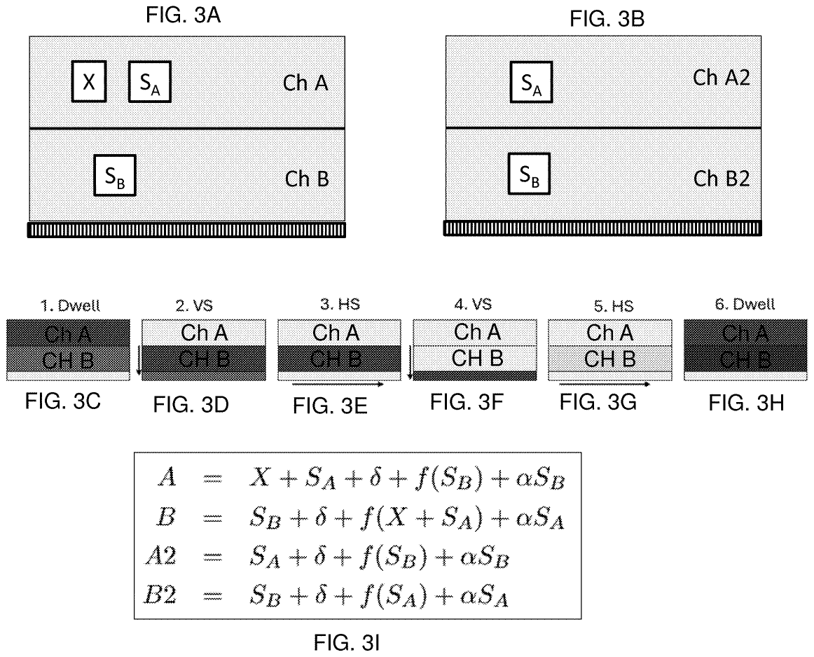

FIGS. 3A-3I are a set of block diagrams and mathematical descriptions indicating sequencing and collection of certain signals and their associated regions of a CCD sensor such as regions 210 and 220 of sensor 200. Although the following discussion may generally apply to any number of channels defined for a spectrometer, FIGS. 3A-3I represents a two-channel example wherein both continuous and discontinuous optical signals are collected. Additional signals are collected which include signals where the discontinuous signal is both on and off. Although this example optical signal collection methodology includes both OES and IEP signals as used to monitor semiconductor processes, it should be understood that any combination of OES signals, IEP signals, continuous, and discontinuous optical signals may be processed for reduced crosstalk according the details described herein.

FIG. 3A represents regions of sensor 200 during an example collection when the signal from a discontinuous source (e.g., light source 150) is observed. Light source 150 and other elements of FIG. 1 are used as examples in the discussion of FIG. 3A. Channel A (e.g., region 210) integrates signals from the discontinuous source X and normally-oriented observed OES signal S_{A} from plasma 130 via interface 140 and fiber optic cable assembly 157. Channel B (e.g., region 220) integrates the signal from non-normally-oriented observed OES signal S_{B} from plasma 130 via interface 142 and fiber optic cable assembly 159. The signal collection related by FIG. 3B may be essentially identical to that represented by FIG. 3A except that during collection the signal from a discontinuous source is not present.

The signals accumulated into the regions of and collected from both Channel A and Channel B include optical and electrical crosstalk signal contributions from the signals incident upon the opposing channel. Generally, crosstalk may be considered the undesirable, inadvertent, inherent, and/or systematic mixing of signals between channels. That is, signals incident upon Channel A crosstalk to Channel B and signals incident upon Channel B crosstalk to Channel A. Either crosstalk contribution in either direction may be similar or different. Herein, for some examples, it will be represented that crosstalk contributions may be equivalent for equally defined channels/regions of a CCD and specific sensor readout configurations. Herein electrical crosstalk may be defined as arising from the CCD readout process and optical crosstalk may be defined as arising from weak scattering of light from one region to another. Hereinafter for simplification but not limitation of the discussed examples, it is assumed that optical crosstalk is small compared to the electrical/readout crosstalk.

FIGS. 3C-3H provide a pictorial representation of the steps associated with the accumulation and collection of signals from the various channels and present how electrical crosstalk arises during operation of the CCD-based spectrometer. Although FIGS. 3C-3H may describe the optical signal exposure configuration of either FIG. 3A or FIG. 3B, for simplicity the immediate discussion will refer to the steps and signals associated with FIG. 3A.

FIG. 3C indicates an initial dwell or integration period for the collection of signals in the channel regions defined for the optical sensor for the spectrometer. Ch A is exposed and accumulates signals X and S_{A} for a predetermined period of time commonly referred to as the integration time of the signal or channel. Ch B is exposed to and accumulates signal S_{B} for the same integration time which may be for example 2 to 1000 ms.

FIG. 3D indicates a vertical shift of the charge collected within the pixels of the regions of the CCD subsequent to the initial dwell or integration period for the collection of signals in the channel regions defined for the optical sensor for the spectrometer. As defined for equal channel sizes, the vertical shifting of charge in the CCD pixels results in the charge originally located in the region associated with Ch A to be now located in the region associated with Ch B as well as the charge originally located in the region associated with Ch B to be now located in the shift register (e.g., shift register 230). This vertical shift may require, for example, 64 individual vertical shifts (clock cycles) for the current example. At a clock rate of 100 KHz, these 64 shifts require 0.64 ms during which period the regions of Ch A and Ch B will be continuously exposed to any continuous light whereby providing crosstalk and mixing of the signals initially incident in the separate regions.

FIG. 3E indicates a horizontal shift of the charge collected within the pixels of the shift register of the CCD subsequent to the vertical shift represented in FIG. 3D. This horizontal shift may require, for example, 1024 individual shifts for the current example. At a clock rate of 100 KHz, these 1024 shifts require 10.24 ms during which period the regions of Ch A and Ch B will be further continuously exposed to any continuous light whereby providing additional crosstalk and mixing of the signals initially incident in the separate regions. At the termination of horizontal shifting the signal content originally accumulated into Ch B corresponding to the state indicated in FIG. 3C and any accumulated crosstalk may have been digitized and stored as signal B.

FIG. 3F indicates a second vertical shift of the charge collected within the pixels of the regions of the CCD subsequent to the first horizontal shift represented in FIG. 3E. Vertical shifting of charge in the CCD pixels results in the charge originally located in the region associated with Ch A to be now located in the shift register. As the CCD regions of Ch A and Ch B will be continuously exposed to any continuous light, additional crosstalk and mixing of the signals will result in the separate regions. This vertical shift may require, for example, 64 individual shifts for the current example. At a clock rate of 100 KHz, these 64 shifts require 0.64 ms.

FIG. 3G indicates a second horizontal shift of the charge collected within the pixels of the shift register of the CCD subsequent to the vertical shift represented in FIG. 3F. This horizontal shift may require, for example, 1024 individual shifts for the current example. At a clock rate of 100 KHz, these 1024 shifts require 10.24 ms during which period the regions of Ch A and Ch B will be continuously exposed to any continuous light whereby providing additional crosstalk and mixing of the signals initially incident in the separate regions. At the termination of this horizontal shifting the signal content originally accumulated into Ch A corresponding to the state indicated in FIG. 3C and any accumulated crosstalk may have been digitized and stored as signal A.

FIG. 3H indicates a subsequent dwell or integration period for the collection of signals in the channel regions defined for the optical sensor for the spectrometer. It should be recognized that upon ending of the dwell or integration period, the regions associated with both Ch A and Ch B may be subject to crosstalk signal contributions due to the timing and shift operations of previous steps. The integration period represented by FIG. 3H, may be identical to or differ from that integration period represented by FIG. 3C. Specifically, if the integration period represented by FIG. 3C is the first integration period of a set of integration periods and shifting operations, the initial signal conditions of the Ch A and Ch B regions may be different from those signal conditions of the CH A and Ch B regions presented by FIG. 3H or may be possibly unknown. If both integration periods represented by FIG. 3C and FIG. 3H are subsequent to any first integration period, they may be considered to be identical (within limits of system timing precision) and to have reached a “steady-state.”

FIG. 3I indicates a set of mathematical equations which may be used to characterize the signals A, B, A2, and B2 resulting from the set of operations indicated in FIGS. 3C-3H: wherein A=signal representation of all contributions to the collected and digitized signal from Ch A including discontinuous signal X, B=signal representation of all contributions to the collected and digitized signal from Ch B including discontinuous signal X, A2=signal representation of all contributions to the collected and digitized signal from Ch A excluding discontinuous signal X, B2=signal representation of all contributions to the collected and digitized signal from Ch B excluding discontinuous signal X, X=signal from the discontinuous lamp, S_{A}=continuous signal originally incident upon Ch A, S_{B}=continuous signal originally incident upon Ch B, δ=background signal, α=electrical crosstalk proportionality value, and f( )=representative function of the optical crosstalk. The optical crosstalk function, ƒ, attenuates and blurs the signals and is a complex function of at least intensity, spectral distribution and physical and optical characteristics of the spectrometer. Optical crosstalk is considered small in the examples presented and will be ignored in further discussion. The electrical crosstalk from one channel to the other is, for example, proportional to only the other channel's continuous signal when any discontinuous signals are integrated prior to any shifting operation. The electrical crosstalk proportionality value α may be a simple scalar value and may be symmetric. For example, the proportion of S_{B} included within signal A and the proportion of S_{A} included within signal B may be equal for equal region sizes and similar pixel shifting operations, or may be asymmetric when the characteristics between the regions and the region pixel shifting operations vary.

Background signal δ may generally be collected during in-field operation of the spectrometer when the unit is placed in the dark. As such the δ term represents the dark level, or offset, contribution to the signals subsequently processed. Note that this level can vary with temperature or other environmental conditions. Electrical crosstalk proportionality value α may generally be determined based upon predetermined operating conditions either at the time of manufacture or during actual operation. Examples of the calculation of α are as follows in subsequent Table 1 and discussion.

| Parameter | Case #1 (ms) | Case # 2 (ms) |
|---|---|---|
| Total Integration Time | 35 | 35 |
| Read 1 | 11.31 | 1.50 |
| Read 2 | 11.31 | 1.50 |
| Dwell Time | 12.38 | 32.00 |
| α | 0.477 | 0.045 |

For an example CCD with 128 vertical pixel rows and 1044 pixels in the horizontal shift register divided into two equal pixel regions (channels), with horizontal clock speeds of 98 kHz for Case #1 and 781 kHz for Case #2, with vertical clock speeds of 98 kHz Case #1 and 390 kHz for Case #2, specific values are summarized in the table above. Each “Read” step involves 64 rows vertical shift and 1044 pixels horizontal shift. Electrical crosstalk proportionality value α may be defined as the ratio of signal during the secondary read (Read 2) to the true signal (Read 1+Dwell Time), where “Dwell” is the time where no charge is shifting and “Integration Time” is the entire time (Dwell and CCD read steps).

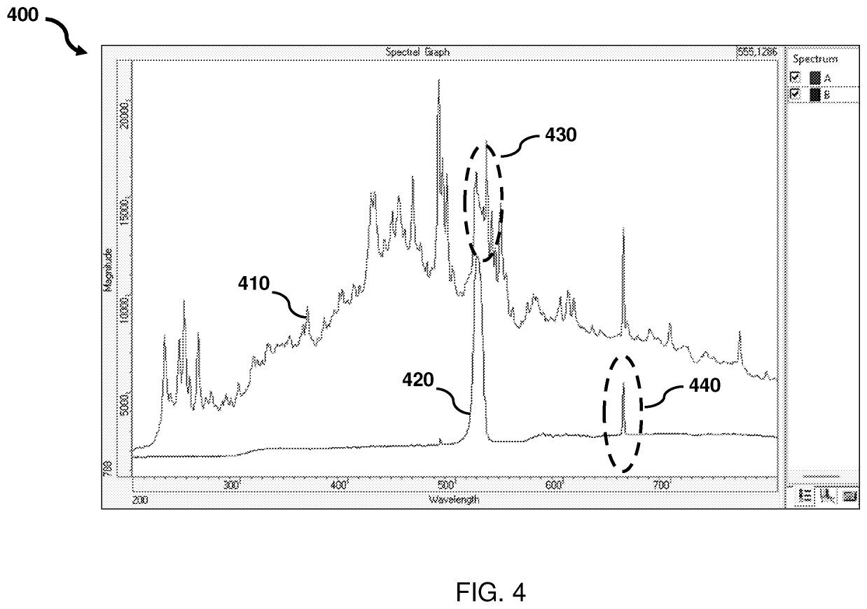

FIG. 4 is a plot 400 of an example of spectral data collected with a discontinuous source active showing the resulting signals and the observed crosstalk. The data of plot 400 is collected in accordance with the block diagrams and sequencing of FIGS. 3A-3I. Spectrum 410 indicates the Ch A spectrum and spectrum 420 indicates the Ch B spectrum resulting from signal collection and digitization as detailed in association with FIGS. 3A-3I. The encircled portion of spectrum 410 denoted by dashed oval 430 shows the crosstalk contamination of the spectrum from Ch A by the signals recorded in Ch B. Similarly, the encircled portion of spectrum 420 denoted by dashed oval 440 shows the crosstalk contamination of the spectrum from Ch B by the signals recorded in Ch A.

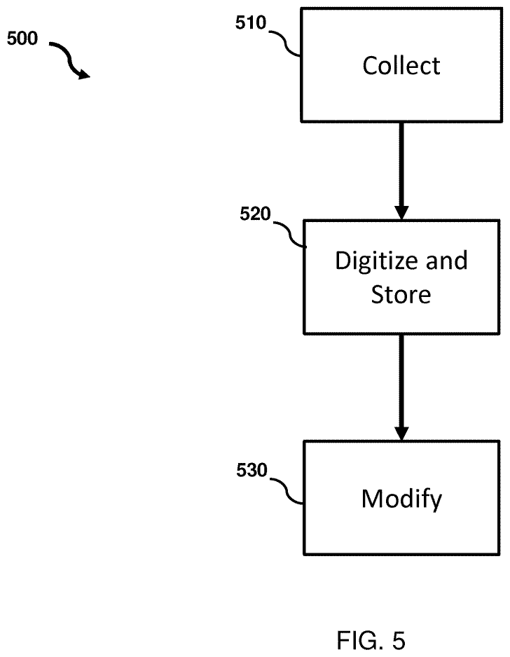

FIG. 5 is flow chart of method 500 detailing the steps for reducing electrical crosstalk from spectral data such as shown in FIG. 4. Method 500 starts with step 510 wherein the various optical signals as disclosed herein in association with FIGS. 3A-3I are collected. Collection may, in general at least, refer to the various subprocesses of signal integration/dwell, vertical pixel shifting, and horizontal pixel shifting during which optical signals are incident upon the regions of the CCD and the incident light is creating charge in the pixels of the regions of the CCD. Next in step 520, the various signals are digitized and stored. Step 520 may include horizontal pixel shifting, A/D conversion of charge quantities or voltages to digital values, and transport, mathematical manipulation by a processor, and storage of those digital values into either volatile or non-volatile memory. Next in step 530, the stored signal values may be modified as detailed and indicated below in association with FIGS. 6-10 using systems such as the optical system 1100 of FIG. 11. For example, processor 1170 may be configured to perform the operations of step 530. Defining conditions and parameters for modification of the stored signals (spectra) may include the earlier predetermination and storing at the time of manufacture values, such as the crosstalk parameters (α) as discussed herein and related to at least one of a number of the channels, a pixel row count description for each of the number of channels, a clock speed of the optical sensor, and an integration time of the collecting of the plurality of optical signals. These conditions and parameters may be based upon specific details on the setup of a spectrometer, such as spectrometers 1110 of FIG. 11 or 160 of FIG. 1. Additional parameters and values required for modification may be collected at a time of use of the spectrometer. One such set of values is the one or more dark signal spectra (δ) required to support the reduction of the crosstalk contributions.

FIGS. 6A-6C are a set of mathematical descriptions for the collected signals and models used for the modification of the signals according to this disclosure. The set of equations indicated in FIG. 6A are a simplified form of those indicated in FIG. 3I upon recognition that the optical crosstalk may be a small contributing factor and may be excluded from the current discussion of the present examples. The set of equations indicated in FIG. 6B indicates the linear relationship between the recorded signals, A₂ and B₂, from Ch A and Ch B respectively and the underlying signals, S_{A} and S_{B}, free of the recorded crosstalk when the crosstalk is identified as symmetric. The set of equations indicated in FIG. 6C indicates the linear relationship between the recorded signals, A₂ and B₂, from regions Ch A and Ch B respectively and the underlying signals, S_{A} and S_{B}, free of the recorded crosstalk when the crosstalk is identified as asymmetric. The linear relationship in this example is specifically for the case of a two-channel system. In an N-channel case corresponding equations can be determined and similarly solved for other symmetric or asymmetric channel maps.

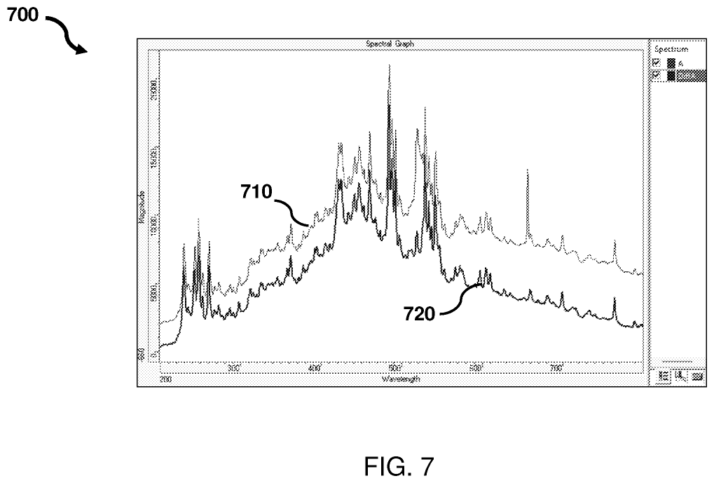

FIGS. 7-10 are a set of plots showing resultant signals following the application of the crosstalk reduction techniques as disclosed herein. FIG. 7 shows a plot 700 of the recorded spectrum 710 from Ch A including the observation of the discontinuous light source which includes crosstalk contributions. Also included is the modified spectrum 720 which results from processing spectrum 710 according to the equations indicated in FIG. 6A. Specifically the A and A₂ signals are subtracted and the result spectrum 720 provides background-subtracted (removes 8 term) discontinuous flashlamp spectrum X with OES signals and any crosstalk contributions therefrom removed (S_{A} and S_{B} removed).

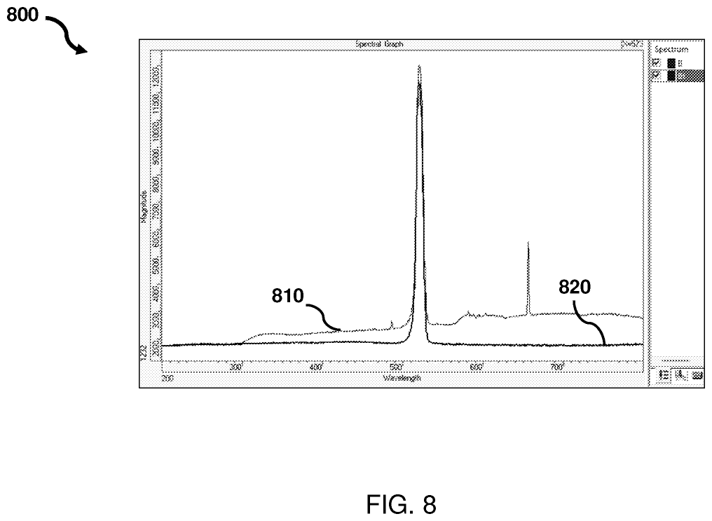

FIG. 8 shows a plot 800 of the recorded spectrum 810 from Ch B including the observation of the continuous light source which includes crosstalk contributions. Also included is the modified spectrum 820 which results from processing spectrum 810 according to the equations indicated in FIG. 6B. Specifically the background signal δ is characterized and is used along with a predetermined value of a to recover the original spectrum S_{B} free of electrical crosstalk from S_{A}.

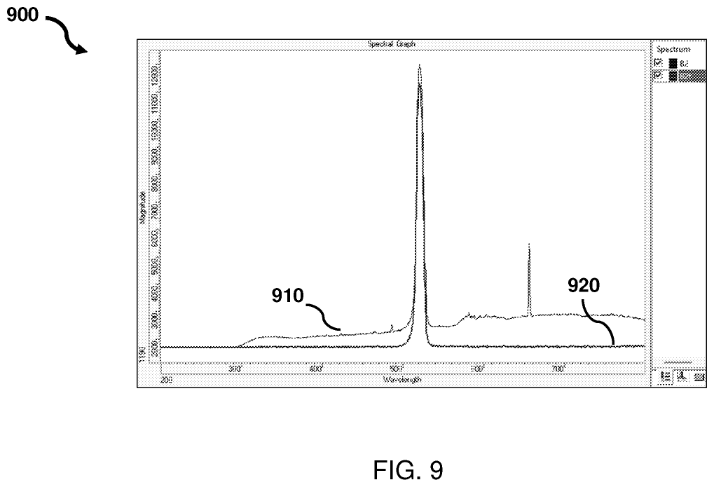

FIG. 9 shows a plot 900 of the recorded spectrum 910 from Ch B including the observation of the continuous light source which includes crosstalk contributions and also specifically during the signal collection where the discontinuous light source is not observed (c.f., FIG. 3B and equations of FIG. 3I referencing B₂). Also included is the modified spectrum 920 which results from processing spectrum 910 according to the equations indicated in FIG. 6B, which is generally when the Ch A and Ch B are the same, or FIG. 6C when Ch A and Ch B can be a different size, such as a different number of rows of pixels. Specifically, the background signal δ is characterized and is used along with a predetermined value of a to recover the original spectrum S_{B} free of electrical crosstalk from S_{A}.

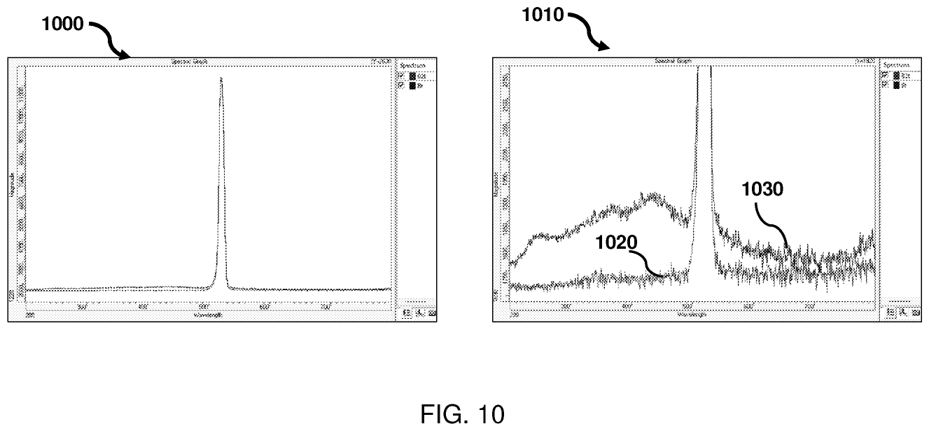

FIG. 10 shows plots 1000 and 1010 which include the spectra recovered via the steps discussed in association with FIGS. 8 and 9. Plot 1010 is a zoomed-in portion of the plot 1000 to enhance details. Spectrum 1020 is the recovered spectrum S_{B} free of electrical crosstalk from S_{A} collected when the discontinuous light source was not observed. Spectrum 1030 is the recovered spectrum S_{B} free of electrical crosstalk from S_{A} collected when the discontinuous light source was observed. The differences between spectra 1020 and 1030 may be identified with optical crosstalk of the discontinuous signal X contributing to spectrum 1030 but not spectrum 1020 due to the existence or lack thereof of X while these individual spectra were collected. Comparison of spectra 1020 and 1030 supports the earlier discussed approximation that the optical crosstalk is small but further emphasizes that appropriate spectrum selection and processing is important for best results of crosstalk reduction.

FIG. 11 is a block diagram of an optical system 1100 including a spectrometer 1110 and specific related systems, in accordance with one embodiment of this disclosure. Spectrometer 1110 may incorporate the system, features, and methods disclosed herein to the advantage of measurement, characterization, analysis, and processing of optical signals from semiconductor processes and may be associated with spectrometer 160 of FIG. 1. Spectrometer 1110 may receive optical signals from external optics 1130, such as via fiber optic cable assemblies 157 or 159, and may, following integration and conversion, send data to external systems 1120, such as output 180 of FIG. 1, which may also be used to control spectrometer 1110 by, for example, selecting a mode of operation or controlling integration timing as defined herein. Spectrometer 1110 may include optical interface 1140 such as a subminiature assembly (SMA) or ferrule connector (FC) fiber optic connector or other opto-mechanical interface. Further optical components 1145 such as slits, lenses, filters and gratings may act to form, guide and chromatically separate the received optical signals and direct them to sensor 1150 for integration and conversion. Low-level functions such as shifting operations of sensor 1150 may be controlled by elements such as FPGA 1160 and processor 1170. Following optical to electrical conversion, analog signals may be directed to A/D convertor 1180 and converted from electrical analog signals to electrical digital signals which may then be stored in memory 1190 for immediate or later use and transmission, such as to external systems 1120 (c.f., signal processor 170 of FIG. 1). Optical system 1100 can modify the stored digital signals as disclosed herein, such as in step 530 of method 500. For example, processor 1170 may be configured to perform the operations of step 530 according to details described in accord with FIG. 31 and FIGS. 6A-6C. Although certain interfaces and relationships are indicated by arrows, not all interactions and control relations are indicated in FIG. 11. For example, a plurality of optical channels may be defined and directed to optical interface 1140 according to the design of a suitable fiber optical cable assembly. As such, spectrometer 1100 can be configured (i.e., designed, constructed, and/or programmed, with the necessary logic and/or features for performing a task or tasks) for processing multiple optical signal channels. Spectrometer 1110 also includes a power supply 1195, which can be a conventional AC or DC power supply typically included with spectrometers.

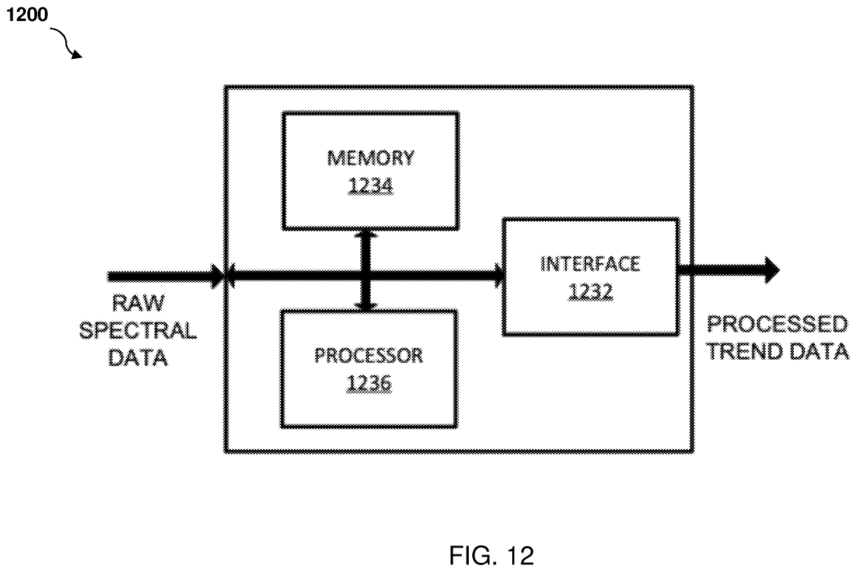

FIG. 12 illustrates a computing device 1200 that can be used for processes disclosed herein, such as identifying signals in spectral data and processing the signals. The computing device 1200 can be a spectrometer or a portion of a spectrometer, such as spectrometer 160 or 1110 disclosed herein. The computing device 1200 may include at least one interface 1232, at least one memory 1234 and at least one processor 1236. The interface 1232 includes the necessary hardware, software, or combination thereof to receive, for example, raw spectral data and to transmit, for example, processed spectral data. A portion of the interface 1232 can also include the necessary hardware, software, or combination thereof for communicating analog or digital electrical signals. The interface 1232 can be a conventional interface that communicates via various communication systems, connections, busses, etc., according to protocols, such as standard protocols or proprietary protocols (e.g., interface 1232 may support I2C, USB, RS232, SPI, or MODBUS). The memory 1234 is configured to store the various software and digital data aspects related to the computing device 1200. Additionally, the memory 1234 is configured to store a series of operating instructions corresponding to an algorithm or algorithms that direct the operation of the processor 1236 when initiated to, for example, process multiple digitized and stored spectra, such as modifying to reduce the effect of crosstalk, as disclosed herein. The resulting processed digitized and stored spectra can then be used to generate improved control signals that more accurately correspond to optical signals collected from processes within a processing chamber. The improved controlled signal can then be used for directing the processes. For example, the improved control signals can be sent to processing tool 110 to direct semiconductor processing of wafer 120 in processing chamber 135. The memory 1234 can also store the defining conditions, values and parameters for the modification of the stored signals (spectra). The memory 1234 can be a non-transitory computer readable medium (e.g., flash memory and/or other media). The processor 1236 is configured to direct the operation of the computing device 1200. As such, the processor 1236 includes the necessary logic to communicate with the interface 1232 and the memory 1234 and perform the functions described herein to identify and process multiple collected spectra, such as in one or more of the steps of method 500.

A portion of the above-described apparatus, systems or methods may be embodied in or performed by various, such as conventional, digital data processors or computers, wherein the computers are programmed or store executable programs of sequences of software instructions to perform one or more of the steps of the methods. The software instructions of such programs or code may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein.

Portions of disclosed embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floptical disks; and hardware devices that are specially configured to store and execute program code, such as ROM and RAM devices. Examples of program code include both machine code, such as produced by a compiler, and files containing higher level code that may be executed by the computer using an interpreter. Configured or “configured to” means, for example, designed, constructed, or programmed, with the necessary logic, algorithms, processing instructions, and/or features for performing a task or tasks.

The changes described above, and others, may be made in the optical measurement systems and subsystems described herein without departing from the scope hereof. For example, although certain examples are described in association with semiconductor wafer processing equipment, it may be understood that the optical measurement systems described herein may be adapted to other types of processing equipment such as roll-to-roll thin film processing, solar cell fabrication or any application where high precision optical measurement may be required. Furthermore, although certain embodiments discussed herein describe the use of a common light analyzing device, such as an imaging spectrograph, it should be understood that multiple light analyzing devices with known relative sensitivity may be utilized. Furthermore, although the term “wafer” has been used herein when describing aspects of the current invention, it should be understood that other types of workpieces such as quartz plates, phase shift masks, LED substrates and other non-semiconductor processing related substrates and workpieces including solid, gaseous and liquid workpieces may be used.

The examples described herein were selected and described in order to best explain the principles of the disclosure and the practical application, and to enable others of ordinary skill in the art to understand the disclosure for various embodiments with various modifications as are suited to the particular use contemplated. The particular examples described herein are in no way intended to limit the scope of the present disclosure as it may be practiced in a variety of variations and environments without departing from the scope and intent of the disclosure. Thus, the present disclosure is not intended to be limited to the examples shown, but is to be accorded the widest scope consistent with the principles and features described herein.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems which perform the specified functions or acts, or combinations of special purpose hardware and computer instructions.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one of skill in the art, the present disclosure may be embodied as a method, system, or computer program product. Accordingly, the present disclosure may take the form of an entirely hardware embodiment, an entirely software embodiment (including firmware, resident software, micro-code, etc.) or an embodiment combining software and hardware aspects all generally referred to herein as a “circuit” or “module.” Furthermore, the present disclosure may take the form of a computer program product on a computer-usable storage medium having computer-usable program code embodied in the medium.

Various aspects of the disclosure can be claimed including the apparatuses, systems, and methods disclosed herein. Aspects disclosed herein and noted in the Summary include:

A. A method for reducing crosstalk between channels in a multichannel optical spectrometer including: (1) collecting a plurality of optical signals from a plurality of channels defined upon an optical sensor of the multichannel optical spectrometer, (2) digitizing and storing the plurality of signals, and (3) modifying one or more of the plurality of digitized and stored signals to reduce signal crosstalk, wherein the modifying is based at least on a number of the channels, a clock speed of the optical sensor, and an integration time of the collecting of the plurality of optical signals.

B. A multichannel optical spectrometer with crosstalk reducing functionality including: (1) a two-dimensional optical sensor for collecting a plurality of optical signals, the two-dimensional optical sensor configured into a plurality of channels, (2) circuitry for digitizing and storing the plurality of signals each from one of the plurality of channels, and (3) a processor for modifying one or more of the plurality of digitized and stored signals to reduce signal crosstalk, wherein the modifying is based at least on a number of the channels, a clock speed of the optical sensor, and an integration time of the collecting of the plurality of optical signals.

C. An optical processing system with crosstalk reducing functionality, comprising: (1) a multichannel optical spectrometer including a two-dimensional optical sensor for collecting a plurality of optical signals, the two-dimensional optical sensor configured into a plurality of channels, circuitry for digitizing and storing the plurality of signals each from one of the plurality of channels, and a first processor for at least partially modifying one or more of the plurality of digitized and stored signals to reduce signal crosstalk based at least on a number of the channels, a clock speed of the optical sensor, and an integration time of the collecting of the plurality of optical signals, and (2) a second processor, external to the multichannel optical spectrometer, for at least partially modifying one or more of the plurality of digitized and stored signals to reduce signal crosstalk based at least on a number of the channels, a clock speed of the optical sensor, and an integration time of the collecting of the plurality of optical signals.

D. A non-transitory computer-readable medium having a series of operating instructions stored thereon that direct operations of a processor when initiated to perform operations comprising: (1) collecting a plurality of optical signals from a plurality of channels defined upon an optical sensor of a multichannel optical spectrometer, (2) digitizing and storing the plurality of signals, and (3) modifying one or more of the plurality of digitized and stored signals to reduce signal crosstalk based at least on a number of the channels, a clock speed of the optical sensor, and an integration time of the collecting of the plurality of optical signals.

Each of aspects A, B, C, and D can have one or more of the following additional elements in combination: Element 1: wherein the plurality of channels includes two channels. Element 2: wherein the modifying of the digitized and stored signals is performed by a processor within the multichannel optical spectrometer. Element 3: wherein the modifying of the digitized and stored signals is performed by a processor external to the multichannel optical spectrometer. Element 4: wherein the modifying is further based upon a dark level signal. Element 5: wherein one or more of the plurality of optical signals includes crosstalk contributions from both electronic crosstalk and optical crosstalk. Element 6: wherein one or more of the plurality of optical signals includes both continuous and discontinuous optical signals. Element 7: wherein collecting the plurality of optical signals includes collecting a first plurality of optical signals wherein the discontinuous optical signal is observed and collecting a second plurality of optical signals wherein the discontinuous optical signal is not observed. Element 8: wherein the modifying each of the plurality of digitized and stored signals to reduce signal crosstalk includes calculating differences between the first and second pluralities of collected optical signals. Element 9: wherein one or more optical signals of the plurality of optical signals includes combinations of IEP and OES optical signals. Element 10: wherein the signal crosstalk between channels is mathematically approximated as a linear combination of the digitized signals from each channel and a dark level signal. Element 11: further including collecting a dark level signal from one or more of the plurality of channels of the optical sensor of the multichannel optical spectrometer. Element 12: further including predetermining and storing parameters and values for modifying the one or more of the plurality of digitized and stored signals to reduce signal crosstalk. Element 13: further including storage for retaining the plurality of digitized and stored signals and storing one or more parameters for modifying the one or more of the plurality of digitized and stored signals to reduce signal crosstalk. Element 14: wherein the processor controls the circuitry for digitizing and storing the plurality of signals. Element 15: wherein the plurality of optical signals are collected from a processing chamber and correspond to a semiconductor process in the processing chamber, wherein the processor is further configured to generate control signals using the modified one or more plurality of digitized and stored signals and send the control signals to a processing tool to improve control of the semiconductor process. Element 16: further including a fiberoptic interface providing the plurality of optical signals to the two-dimensional optical sensor.

What is claimed is:

1. A method for reducing crosstalk between channels in a multichannel optical spectrometer, comprising:
collecting a plurality of optical signals from a plurality of channels defined upon an optical sensor of the multichannel optical spectrometer,
digitizing and storing the plurality of signals, and
modifying one or more of the plurality of digitized and stored signals to reduce signal crosstalk, wherein the modifying is based at least on a number of the channels, a clock speed of the optical sensor, and an integration time of the collecting of the plurality of optical signals.

2. The method as recited in claim 1, wherein the plurality of channels includes two channels.

3. The method as recited in claim 1, wherein the modifying of the digitized and stored signals is performed by a processor within the multichannel optical spectrometer.

4. The method as recited in claim 1, wherein the modifying of the digitized and stored signals is performed by a processor external to the multichannel optical spectrometer.

5. The method as recited in claim 1, wherein the modifying is further based upon a dark level signal.

6. The method as recited in claim 1, wherein one or more of the plurality of optical signals includes crosstalk contributions from both electronic crosstalk and optical crosstalk.

7. The method as recited in claim 1, wherein one or more of the plurality of optical signals includes both continuous and discontinuous optical signals.

8. The method as recited in claim 7, wherein collecting the plurality of optical signals includes collecting a first plurality of optical signals wherein the discontinuous optical signal is observed and collecting a second plurality of optical signals wherein the discontinuous optical signal is not observed.

9. The method as recited in claim 8, wherein the modifying each of the plurality of digitized and stored signals to reduce signal crosstalk includes calculating differences between the first and second pluralities of collected optical signals.

10. The method as recited in claim 1, wherein one or more optical signals of the plurality of optical signals includes combinations of IEP and OES optical signals.

11. The method as recited in claim 1, wherein the signal crosstalk between channels is mathematically approximated as a linear combination of the digitized signals from each channel and a dark level signal.

12. The method as recited in claim 1, further including collecting a dark level signal from one or more of the plurality of channels of the optical sensor of the multichannel optical spectrometer.

13. The method as recited in claim 1, further including predetermining and storing parameters and values for modifying the one or more of the plurality of digitized and stored signals to reduce signal crosstalk.

14. A multichannel optical spectrometer with crosstalk reducing functionality, comprising:
a two-dimensional optical sensor for collecting a plurality of optical signals, the two-dimensional optical sensor configured into a plurality of channels,
circuitry for digitizing and storing the plurality of signals each from one of the plurality of channels, and
a processor for modifying one or more of the plurality of digitized and stored signals to reduce signal crosstalk, wherein the modifying is based at least on a number of the channels, a clock speed of the optical sensor, and an integration time of the collecting of the plurality of optical signals.

15. The multichannel optical spectrometer as recited in claim 14, further including storage for retaining the plurality of digitized and stored signals and storing one or more parameters for modifying the one or more of the plurality of digitized and stored signals to reduce signal crosstalk.

16. The multichannel optical spectrometer as recited in claim 14, wherein the processor controls the circuitry for digitizing and storing the plurality of signals.

17. The multichannel optical spectrometer as recited in claim 14, wherein the plurality of optical signals are collected from a processing chamber and correspond to a semiconductor process in the processing chamber, wherein the processor is further configured to generate control signals using the modified one or more plurality of digitized and stored signals and send the control signals to a processing tool to improve control of the semiconductor process.

18. An optical processing system with crosstalk reducing functionality, comprising:
a multichannel optical spectrometer comprising:
a two-dimensional optical sensor for collecting a plurality of optical signals, the two-dimensional optical sensor configured into a plurality of channels,
circuitry for digitizing and storing the plurality of signals each from one of the plurality of channels, and
a first processor for at least partially modifying one or more of the plurality of digitized and stored signals to reduce signal crosstalk based at least on a number of the channels, a clock speed of the optical sensor, and an integration time of the collecting of the plurality of optical signals, and
a second processor, external to the multichannel optical spectrometer, for at least partially modifying one or more of the plurality of digitized and stored signals to reduce signal crosstalk based at least on a number of the channels, a clock speed of the optical sensor, and an integration time of the collecting of the plurality of optical signals.

19. The optical processing system as recited in claim 18, further including a fiberoptic interface providing the plurality of optical signals to the two-dimensional optical sensor.

20. A non-transitory computer-readable medium having a series of operating instructions stored thereon that direct operations of a processor when initiated to perform operations comprising:
collecting a plurality of optical signals from a plurality of channels defined upon an optical sensor of a multichannel optical spectrometer;
digitizing and storing the plurality of signals; and
modifying one or more of the plurality of digitized and stored signals to reduce signal crosstalk based at least on a number of the channels, a clock speed of the optical sensor, and an integration time of the collecting of the plurality of optical signals.
